(19) United States
(12) Patent Application Publication
(10) Pub. No.: US 2026/0113001 A1
(43) Pub. Date: Apr. 23, 2026

(54) AMPLIFYING CIRCUIT AND RF CIRCUIT INCLUDING THE SAME

(71) Applicant: Samsung Electronics Co., Ltd., Suwon-si (KR)

(72) Inventors: Jongmin Jeong, Suwon-si (KR); Juhee Son, Suwon-si (KR); Sangmin Yoo, Suwon-si (KR); Sangsung Lee, Suwon-si (KR); JONGSOO LEE, Suwon-si (KR)

(73) Assignee: Samsung Electronics Co., Ltd., Suwon-si (KR)

(21) Appl. No.: 19/235,387

(22) Filed: Jun. 11, 2025

(30) Foreign Application Priority Data
Oct. 18, 2024 (KR) 10-2024-0143230

(51) Int. Cl. H03F 1/02; H03F 3/24; H03F 3/45; H04B 1/04

(52) U.S. Cl. CPC H03F 1/0233; H03F 3/245; H03F 3/45641; H04B 1/04; H03F 2200/451; H04B 2001/0408

(57) ABSTRACT

An amplifying circuit includes a first amplifier circuit, a second amplifier circuit, and a common mode feedback circuit. The first amplifier circuit includes a first transistor configured to receive a first input voltage signal and connected to a first node and a second node. A first current source located between a power voltage line and the first node is configured to supply a first current to the first transistor. A second current source is located between the first node and the second node and is connected in parallel with the first transistor, wherein a path of a first current flowing from the first node to the second node is determined based on a comparison of the first voltage level of the first input voltage signal to a first predetermined voltage level.

### CROSS-REFERENCE TO RELATED APPLICATION

This application claims priority from Korean Patent Application No. 10-2024-0143230, filed on Oct. 18, 2024, in the Korean Intellectual Property Office, and all the benefits accruing therefrom under 35 U.S.C. § 119, the entire contents of which are incorporated herein by reference.

### TECHNICAL FIELD

Apparatuses consistent with some embodiments of the present disclosure relate to amplifying circuits and radio-frequency (RF) circuits including the amplifying circuits, and more particularly, to amplifying circuits capable of reducing current consumption.

### BACKGROUND

In amplifiers, generally the output common mode of the DC level may be selected as a level capable of maximizing a swing range and gain of the output of the amplifier. If the bias voltage of an amplifier providing a common mode is fixed, the output signal range may not be secured or the gain may be deteriorated, for example, due to changes in power, temperature, process conditions, difference in amplifier output between the input common mode and the output common mode, or changes in the common output mode due to noise.

In order to ensure a stable amplifier output, an amplifier is configured by adding a feedback circuit to an output terminal of the amplifier, which is referred to as a common mode feedback circuit (CMFB). It is desirable to reduce the current consumption of the amplifier while ensuring stable output of the amplifier.

### SUMMARY

Some embodiments consistent with the present disclosure provide an amplifying circuit capable of reducing current consumption and a RF circuit including the same, an amplifying circuit with reduced current consumption and an RF circuit including the same, or an amplifying circuit with improved operation stability and an RF circuit including the same.

The objectives to be solved by some embodiments of the present disclosure are not limited to the objectives mentioned above, and other objectives may be clearly understood by one of ordinary skill in the art from the following description.

Some embodiments consistent with the present disclosure provide an amplifying circuit comprising: a first amplifier configured to receive first input voltages of a first level, output voltages generated based on a first current flowing through first paths as second input voltages, receive the first input voltages of a second level different from the first level, and output voltages generated based on second current flowing through second paths different from the first paths as second input voltages; a second amplifier configured to receive the second input voltages and adjust voltage levels of output voltages generated by amplifying the second input voltages; and a common mode feedback circuit configured to receive a first output voltage among the output voltages through a first output node, receive a second output voltage among the output voltages through a second output node, and adjust voltage levels of the first output voltage and the second output voltage according to the strength of a feedback voltage based on the first output voltage, the second output voltage, and a reference voltage.

Some embodiments consistent with the present disclosure provide an amplifying circuit comprising a first amplifier circuit. The first amplifier circuit comprises a first transistor configured to receive a first input voltage signal, the first transistor being connected to a first node and a second node, a first current source located between a power voltage line and the first node and configured to supply a first current to the first transistor, and a second current source located between the first node and the second node and connected in parallel with the first transistor, wherein when a first voltage level of the first input voltage signal is lower than a first predetermined voltage level, the first current is configured to flow in a first path from the first node to the second node through the first transistor, the first transistor configured to output a third input voltage to the second node based on the first current flowing through the first transistor, and when the first voltage level of the first input voltage signal is higher than the first predetermined voltage level, the first current is configured to flow in a second path from the first node to the second node through the second current source.

Some embodiments consistent with the present disclosure provide an RF circuit. The RF circuit comprises a transmission signal (TX) filter configured to filter a first transmission signal input from an external device and form a filtered first transmission signal, a transmission signal (TX) mixer configured to receive the filtered first transmission signal and up-convert a frequency of the filtered first transmission signal to generate a second transmission signal, and a power amplifier configured to receive the second transmission signal and amplify the second transmission signal. The TX filter comprises a first amplifier configured to receive the first transmission signal and an inverted signal of the first transmission signal as a first input signal and a second input signal, respectively, amplify each of the first input signal and the second input signal, and output a third input signal and a fourth input signal corresponding to an amplified first input signal and an amplified second input signal, respectively. The TX filter comprises a second amplifier configured to receive the third input signal and the fourth input signal, amplify the third input signal and the fourth input signal, output a first output signal and a second output signal, and adjust a voltage level of the first and the second output signal based on a voltage level of the third and the fourth input signal. The TX filter comprises a common mode feedback circuit configured to receive the first output signal through a first output node, receive the second output signal through a second output node, generate a feedback current based on a reference voltage and a common mode output voltage determined based on the first output signal and the second output signal, and adjust a voltage level of the first output node and a voltage level of the second output node based on the feedback current.

### BRIEF DESCRIPTION OF THE DRAWINGS

The accompanying drawings are included to provide a further understanding of disclosed exemplary embodiments, and are incorporated in and constitute a part of this specification. In the drawings:

FIG. 1 illustrates a block diagram showing an exemplary communication device, consistent with some embodiments of the present disclosure.

FIG. 2 illustrates a circuit diagram of an exemplary filter including an amplifying circuit, consistent with some embodiments of the present disclosure.

FIG. 3 illustrates a circuit diagram of an exemplary amplifying circuit, consistent with some embodiments of the present disclosure.

FIG. 4 illustrates a circuit diagram of an exemplary common mode feedback circuit, consistent with some embodiments of the present disclosure.

FIG. 5 illustrates a circuit diagram of an exemplary amplifying circuit, consistent with some embodiments of the present disclosure.

FIG. 6 illustrates a circuit diagram of an exemplary amplifying circuit, consistent with some embodiments of the present disclosure.

FIG. 7 illustrates a circuit diagram of an exemplary amplifying circuit consistent with some embodiments of the present disclosure.

FIG. 8 illustrates a circuit diagram of an exemplary common mode feedback circuit, consistent with some embodiments of the present disclosure.

FIG. 9 illustrates a circuit diagram of an exemplary amplifying circuit, consistent with some embodiments of the present disclosure.

FIG. 10 illustrates a circuit diagram of an exemplary amplifying circuit, consistent with some embodiments of the present disclosure.

FIG. 11 illustrates a circuit diagram of an exemplary amplifying circuit, consistent with some embodiments of the present disclosure.

FIG. 12 illustrates a circuit diagram of an exemplary amplifying circuit, consistent with some embodiments of the present disclosure.

FIG. 13 illustrates a graph comparing the current consumption of an amplifying circuit, consistent with some embodiments of the present disclosure.

FIG. 14 illustrates a block diagram showing an exemplary communication device, consistent with some embodiments of the present disclosure.

FIG. 15 illustrates a block diagram showing an exemplary mobile device to which a communication device is applied, consistent with some embodiments of the present disclosure.

### DETAILED DESCRIPTION

In the following detailed description, only certain embodiments of the present disclosure have been shown and described, simply by way of illustration. As those skilled in the art would realize, the described embodiments may be modified in various different ways, all without departing from the spirit or scope of the present disclosure.

Accordingly, the drawings and description are to be regarded as illustrative in nature and not restrictive. Like reference numerals designate like elements throughout the specification. In the flowchart described with reference to the drawing, the order of operations may be changed, several operations may be merged, some operations may be split, and certain operations may not be performed.

Additionally, expressions written in the singular can be interpreted as singular or plural, unless explicit expressions such as “one” or “singular” are used. Terms including ordinal numbers, such as first, second, etc., may be used to describe elements of various configurations, but components are not limited by such terms. Such terms may be used to distinguish one component from another.

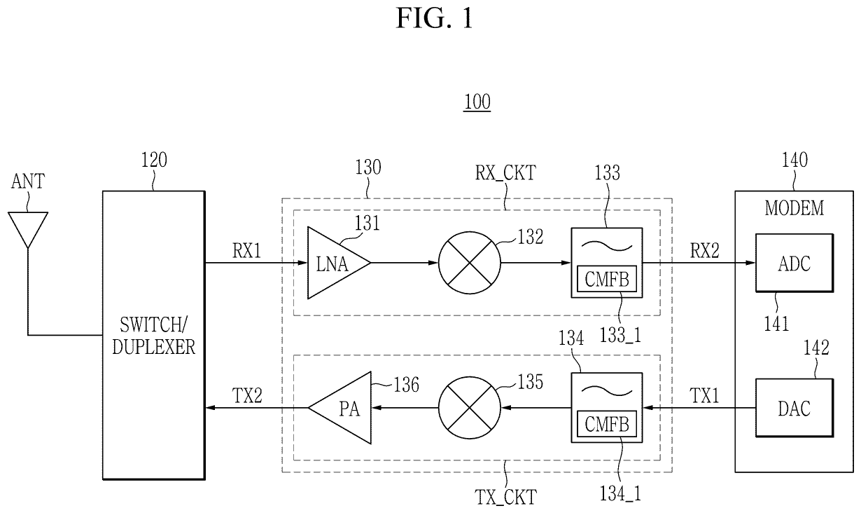

FIG. 1 illustrates a block diagram showing an exemplary communication device, consistent with some embodiments of the present disclosure.

Referring to FIG. 1, the communication device 100 may access a wireless communication system by transmitting and receiving a signal through an antenna ANT. The wireless communication system which the communication device 100 can access may be referred to as RAT (Radio Access Technology), and may be a wireless communication system utilizing a cellular network such as a next generation wireless system, 5G (5th Generation) wireless system, an LTE (Long Term Evolution) wireless system, an LTE-Advanced system, a CDMA (Code Division Multiple Access) wireless system, a GSM (Global System for Mobile communications) system, a WLAN (Wireless Local Area Network) system, or any other arbitrary wireless communication system. Hereinafter, it will be described assuming that the wireless communication system accessed by the communication device 100 is a wireless communication system using a cellular network, but embodiments of the present disclosure are not limited thereto.

A wireless communication network of a wireless communication system may support communication between a plurality of wireless communication devices including communication device 100 by sharing available network resources. For example, in a wireless communication network, information can be transmitted using various multiple access methods such as CDMA (Code Division Multiple Access), FDMA (Frequency Division Multiple Access), TDMA (Time Division Multiple Access), OFDMA (Orthogonal Frequency Division Multiple Access), SC-FDMA (Single Carrier Frequency Division Multiple Access), OFDM-FDMA, OFDM-TDMA, OFDM-CDMA, and the like.

The communication device 100 may refer to any device accessing a wireless communication system. A base station (BS), as an example of the communication device 100, may generally refer to a fixed point (fixed station) that communicates with user devices and/or other base stations, and may exchange data and control information by communicating with user devices and/or other base stations. For example, a base station may also be referred to as a Node B, an evolved-Node B (eNB), a Next generation Node B (gNB), a sector, a site, a Base Transceiver System (BTS), an Access Pint (AP), a relay node, a Remote Radio Head (RRH), a Radio Unit (RU), a small cell, and the like. Here, base station or cell may be interpreted as a comprehensive meaning indicating some region or function covered by a BSC (Base Station Controller) in CDMA, a Node-B in WCDMA, and an eNB or sector (site) in LTE, and may encompass various coverage regions such as megacells, macrocells, microcells, picocells, femtocells, and relay nodes, RRHs, RUs, and small cell communication ranges.

A user equipment (UE), as an example of the communication device 100, may be fixed or mobile, and may refer to any device capable of communicating with a base station to transmit and receive data and/or control information. For example, a user device may be referred to as a terminal equipment, a mobile station (MS), a mobile terminal (MT), a user terminal (UT), a subscriber station (SS), a wireless device, a handheld device, etc. Hereinafter, the communication device 100 will be assumed to be a user equipment (UE), but the embodiments of the present disclosure are not limited thereto.

The communication device 100 may include a switch/duplexer 120, a transceiver 130, and a modem 140. The switch/duplexer 120 may provide a signal received through an antenna ANT to the transceiver 130 as the first received signal RX1, and may also provide a second transmission signal TX2 received from the transceiver 130 to the antenna ANT.

The transceiver 130 may include a receiving circuit (or referred to as receiver) RX_CKT and a transmitting circuit (or referred to as transmitter) TX_CKT.

The receiving circuit RX_CKT may generate a second received signal RX2 by processing the first received signal RX1 received from the switch/duplexer 120 and provide the second received signal RX2 to the modem 140. The receiving circuit RX_CKT may include a low noise amplifier LNA 131, an RX mixer 132, and an RX filter 133, in order to process the first received signal RX1. The low noise amplifier 131 amplifies the input signal to generate an output signal, and the RX mixer 132 may perform frequency down-conversion on the input signal of the first radio-frequency (RF) band to generate a baseband output signal. The RX filter 133 may generate the second received signal RX2 by removing unwanted parts from the input signal.

The transmitting circuit TX_CKT may generate a second transmission signal TX2 by processing the first transmission signal TX1 received from modem 140 and provide the second transmission signal TX2 to the switch/duplexer 120. The transmitting circuit TX_CKT may include a TX filter 134, a TX mixer 135, and a power amplifier PA 136, to process the first transmission signal TX1. The TX filter 134 may filter the first transmission signal TX1 received from modem 140 and provide the filtered signal to the TX mixer 135. The TX mixer 135 performs frequency up-conversion on the signal received from TX filter 134 to generate an output signal of the second RF band, and power amplifier 136 may amplify the input signal to generate a second transmission signal TX2.

In some embodiments, the RX filter 133 and the TX filter 134 may include one or more amplifiers. The range of the output signal of the amplifiers in the RX filter 133 and TX filter 134 may change due to various causes. For example, the range of the output signal of the amplifiers in the RX filter 133 and TX filter 134 may change if a signal larger than expected may be input as an input signal to RX filter 133 and TX filter 134, or if the common mode output voltage is changed by noise. In this way, the level of the common mode output voltage of the amplifiers in the RX filter 133 and TX filter 134 may be biased to a level other than a predetermined level (e.g., a level between the power supply voltage and the ground voltage), which may limit the operation of the amplifiers.

In some embodiments, an amplifier in the RX filter 133 and the TX filter 134 may adjust the voltage level of the output signal when a signal larger than expected is input as the input signal. For example, the amplifiers in the RX filter 133 and TX filter 134 may be two-stage amplifiers, and a second amplifier may lower the voltage level of the output signal based on the signal output from a first amplifier when a signal larger than expected is input to the first amplifier as an input signal.

In some embodiments, for adjusting the level of the common mode output voltage, the RX filter 133 and the TX filter 134 may include a common mode feedback circuit (CMFB) 133_1 and 134_1, respectively. One or both of the common mode feedback circuits 133_1, 134_1 may be a negative feedback circuit detecting a common mode output voltage of the amplifiers in the RX filter 133 and TX filter 134, comparing the detected common mode output voltage with a reference voltage, and making the detected common mode output voltage closer to the reference voltage based on the result of the comparison. In some embodiments, a common mode feedback circuit 133_1, 134_1 may include a pull-up circuit increasing the voltage level of the common mode output voltage when the common mode output voltage is lower than the reference voltage. In some embodiments, a common mode feedback circuit 133_1, 134_1 may include a pull-down circuit decreasing the voltage level of the common mode output voltage when the common mode output voltage is higher than the reference voltage. Also, although the amplifiers in the RX filter 133 and the TX filter 134 have been described, not limited thereto, the low-noise amplifier 131 and the power amplifier 136 may also include a common mode feedback circuit according to an embodiment.

The modem 140 may process the first transmission signal TX1 containing the information to be transmitted according to a predetermined communication method and the modem 140 may process the second received signal RX2 according to a predetermined communication method. For example, the modem 140 may process a signal to be transmitted or a signal received according to a communication method such as OFDM OFDMA, WCDMA, HSPA+, and the like. In addition, the modem 140 may process the first transmission signal TX1 and the second received signal RX2 according to various types of communication methods (e.g., various communication methods where techniques of modulating or demodulating the amplitude and/or frequency of the first transmission signal TX1 and the second received signal RX2 are applied). The modem 140 may include an analog/digital converter (ADC) 141 and a digital/analog converter (DAC) 142.

In some embodiments, the ADC 141 may convert the second received signal RX2 into a digital signal and output it. Information may be extracted from the output digital signal by digital processing such as filtering, demodulation, decoding, and the like.

In some embodiments, the DAC 142 may convert a digital signal to an analog signal, which is to be transmitted into a first transmission signal TX1. The DAC 142 may generate the first transmission signal TX1 through digital processing such as filtering, modulation, encoding of information and the like, and may output the first transmission signal TX1.

For reference, the configuration of the communication device 100 illustrated in FIG. 1 is merely exemplary, and not limited thereto. It is to be appreciated that the communication device 100 may be configured in various ways depending on the communication protocol or communication method.

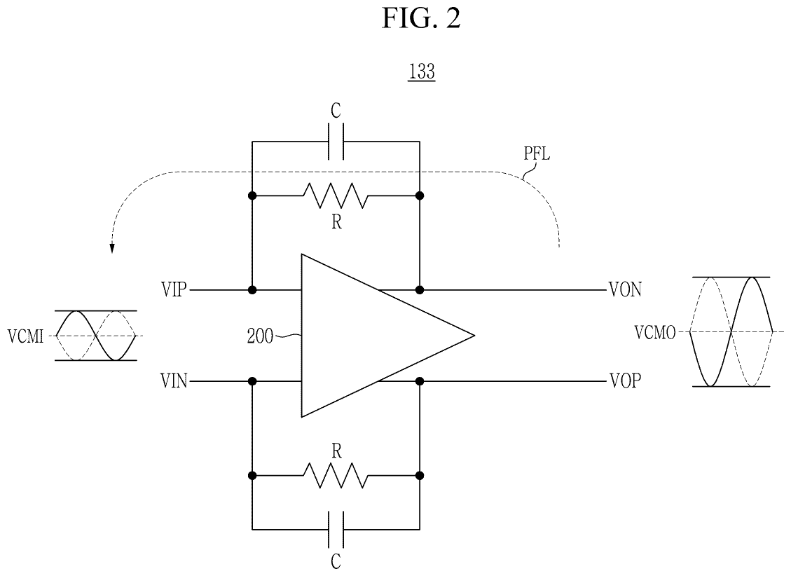

FIG. 2 illustrates a circuit diagram of a filter including an amplifying circuit, consistent with some embodiments of the present disclosure. While FIG. 2 illustrates an RX filter 133 for convenience of explanation, the TX filter (134 in FIG. 1) may also have the same or similar configuration.

Referring to FIG. 2, the RX filter 133 may include an amplifying circuit 200 configured to receive input voltages VIP, VIN, a feedback resistor R and a feedback capacitor C connected in parallel to each other between an input terminal and an output terminal of the amplifying circuit 200.

The amplifying circuit 200 may receive the input voltages VIP, VIN as an input signal and output the amplified output voltages VOP, VON as an output signal. The gain and cutoff frequency of RX filter 133 may be determined depending on the resistance value of the feedback resistor R and the capacitance of the feedback capacitor C. For example, the cutoff frequency of RX filter 133 may have a characteristic that is inversely proportional to the resistance value of the feedback resistor R and the capacitance of the feedback capacitor C. In some embodiments, the feedback resistor R may be a variable resistor and the feedback capacitor C may be a variable capacitor.

The amplifying circuit 200, feedback resistor R, and feedback capacitor C of the RX filter 133 may form a positive feedback loop PFL for the common mode output voltage VCMO. When the voltage level of the common mode output voltage VCMO changes significantly due to an unexpectedly large input voltage, the voltage level of the common mode input voltage VCMI may also change due to the positive feedback loop PFL. Here, the common mode output voltage VCMO may correspond to an average value of the output voltages VOP, VON, and the common mode input voltage VCMI may correspond to an average value of the input voltages VIP, VIN. For example, if the voltage level of the common mode output voltage VCMO becomes higher than a predetermined level due to unexpectedly large input voltages VIP, VIN, the voltage level of the common mode input voltage VCMI may also increase due to the positive feedback loop PFL. As a result, abnormal operations such as amplifier oscillation can be detected.

In some embodiments, an amplifier in an amplifying circuit 200 may decrease the level of an output voltage when an unexpectedly large input voltage is received. Alternatively, in some embodiments, the common mode feedback circuit in the amplifying circuit 200 may adjust the level of the common mode output voltage VCMO if the voltage level of the common mode output voltage VCMO changes significantly. This can improve the stability of the amplification circuit 200. The gain of the positive feedback loop PFL may be determined by the resistance value of the feedback resistor R and the capacitance of the feedback capacitor C.

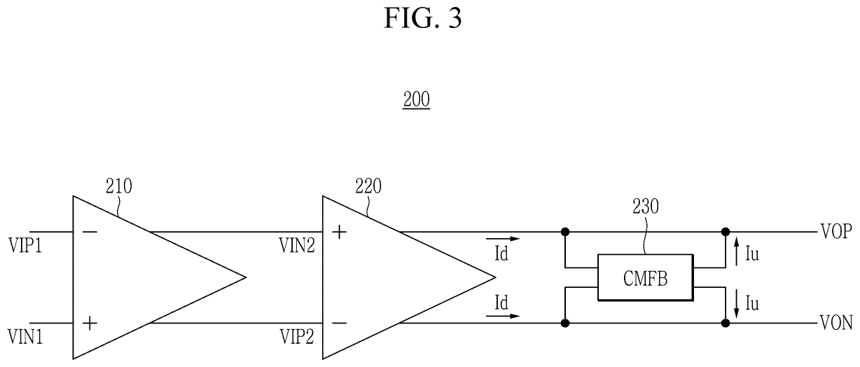

The internal structure of the amplifying circuit 200 is described with reference to FIG. 3 to FIG. 12.

FIG. 3 illustrates a circuit diagram of an exemplary amplifying circuit, consistent with some embodiments of the present disclosure.

In some embodiments, the amplifying circuit 200 may include a first amplifier 210, a second amplifier 220, and a common mode feedback circuit 230. The first amplifier 210 may receive the first input voltage VIP1 and the second input voltage VIN1, and may output a third input voltage VIN2 and a fourth input voltage VIP2 by amplifying the first input voltage VIP1 and the second input voltage VIN1. In some embodiments, the first input voltage VIP1 and the second input voltage VIN1 may be differential signals having opposite phases, and the third input voltage VIN2 and the fourth input voltage VIP2 may also be differential signals having opposite phases. The second amplifier 220 may receive the third input voltage VIN2 and the fourth input voltage VIP2, and may output a first output voltage VOP and a second output voltage VON by amplifying the third input voltage VIN2 and the fourth input voltage VIP2, respectively. In some embodiments, the first output voltage VOP and the second output voltage VON may be differential signals having opposite phases. The first amplifier 210 and the second amplifier 220 may be inverting amplifiers configured to invert the phase of the input signal (e.g., first input voltage VIP1, the second input voltage VIN1, third input voltage VIN2, and the fourth input voltage VIP2).

As described above with respect to FIG. 2, the voltage levels of the first input voltage VIP1 and the second input voltage VIN1 may also change due to the positive feedback loop PFL when the voltage levels of the first output voltage VOP and the second output voltage VON change significantly due to an input signal larger than expected. For example, the voltage levels of the first input voltage VIP1 and the second input voltage VIN1 may become higher due to the positive feedback loop PFL when the first output voltage VOP and the second output voltage VON become higher than predetermined voltage levels due to high levels of the first input voltage VIP1 and the second input voltage VIN1.

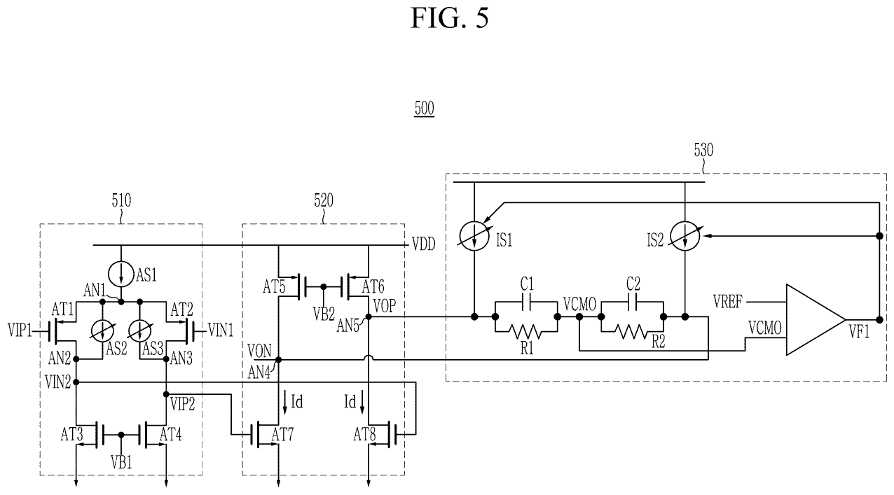

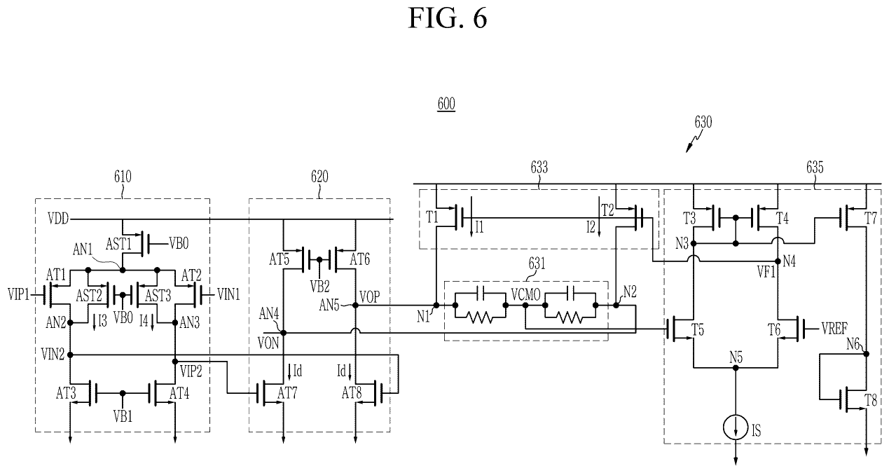

In some embodiments, when the first amplifier 210 may receive a high level of first input voltage VIP1 and second input voltage VIN1, the second amplifier 220 may generate a pull-down current Id as a feedback current for controlling the first output voltage VOP and the second output voltage VON based on the third input voltage VIN2 and the fourth input voltage VIP2 received from the first amplifier 210. Specifically, when the first input voltage VIP1 and the second input voltage VIN1 increase, the first amplifier 210 may form a current path for output of the third input voltage VIN2 and the fourth input voltage VIP2. The second amplifier 220 may receive the third input voltage VIN2 and the fourth input voltage VIP2, generate a pull-down current Id that lowers the voltage levels of the first output voltage VOP and the second output voltage VON, and thereby may decrease the voltage levels of the first output voltage VOP and the second output voltage VON. A detailed explanation is described with reference to FIG. 5 and FIG. 6.

In some embodiments, the common mode feedback circuit 230 may receive a first output voltage VOP and a second output voltage VON, and may adjust the first output voltage VOP and the second output voltage VON based on a difference between a voltage which is determined by the first output voltage VOP and the second output voltage VON, and a reference voltage. For example, the common mode feedback circuit 230 may generate a pull-up current Iu as a feedback current that adjusts the first output voltage VOP and the second output voltage VON for an average voltage of the first output voltage VOP and the second output voltage VON to be substantially same as the reference voltage. Alternatively, the common mode feedback circuit 230 may decrease the voltage levels of the first output voltage VOP and the second output voltage VON so that the average voltage of the first output voltage VOP and the second output voltage VON become substantially same as the reference voltage.

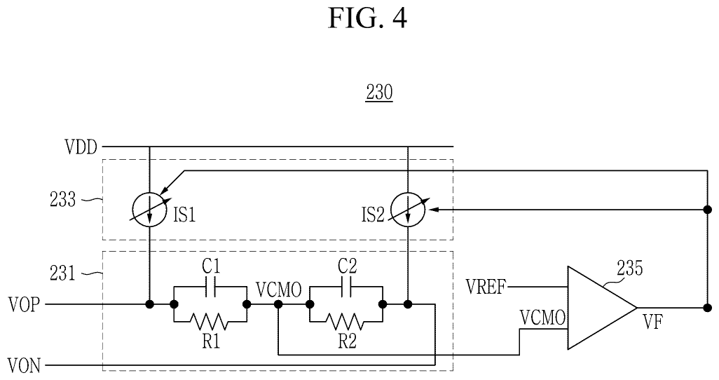

FIG. 4 illustrates a circuit diagram of an exemplary common mode feedback circuit (e.g., common mode feedback circuit 230) consistent with some embodiments of the present disclosure.

In some embodiments, the common mode feedback circuit 230 may include a common mode voltage output circuit 231, an output voltage adjusting circuit 233, and an amplifier 235.

In some embodiments, the common mode voltage output circuit 231 may output a common mode output voltage VCMO based on the first output voltage VOP and the second output voltage VON. In some embodiments, the common mode output voltage VCMO may correspond to an average value of the first output voltage VOP and the second output voltage VON. The common mode voltage output circuit 231 may include a first resistor R1 and a first capacitor C1 connected in parallel, and a second resistor R2 and a second capacitor C2 connected in parallel. In some embodiments, the common mode output voltage VCMO may include a value averaging the first output voltage VOP and the second output voltage VON based on the impedance values associated with the first resistor R1 and the first capacitor C1 and with the second resistor R2 and the second capacitor C2.

In some embodiments, the amplifier 235 may receive common mode output voltage VCMO from common mode voltage output circuit 231, and may generate feedback voltage VF for controlling first output voltage VOP and second output voltage VON based on the common mode output voltage VCMO and reference voltage VREF.

In some embodiments, the output voltage adjusting circuit 233 may include a first variable current source IS1 and a second variable current source IS2. For example, the first variable current source IS1 may be connected between the power voltage VDD line and the first output voltage VOP node, and the second variable current source IS2 may be connected between the power voltage VDD line and the second output voltage VON node. The output voltage adjusting circuit 233 may pull up the voltage levels of the first output voltage VOP and the second output voltage VON based on the feedback voltage VF so that the common mode output voltage VCMO becomes the first voltage level. If the voltage level of the common mode output voltage VCMO is lower than the voltage level of the reference voltage VREF, the pull-up currents from the first variable current source IS1 and the second variable current source IS2 may increase based on the feedback voltage VF received from the amplifier 235, and the voltage levels of the first output voltage VOP and the second output voltage VON may be pulled up so that the common mode output voltage VCMO becomes the first voltage level. The first voltage level may be the voltage level of the reference voltage VREF, but is not limited thereto.

It is to be appreciated that the common mode feedback circuit 230 illustrated in FIG. 4 is exemplary, and the circuit structure of the common mode feedback circuit 230 is not limited thereto. For example, although the common mode feedback circuit 230 has been described as pulling up the voltage levels of the first output voltage VOP and the second output voltage VON, the common mode feedback circuit 230 may also pull down the voltage levels of the first output voltage VOP and the second output voltage VON so that the average voltage of the first output voltage VOP and the second output voltage VON become substantially same as the reference voltage. In some embodiments, the first variable current source IS1 of the output voltage adjusting circuit 233 may be connected between the first output voltage VOP node and the ground voltage VSS line, and the second variable current source IS2 may be connected between the second output voltage VON node and the ground voltage VSS line. The first variable current source IS1 and the second variable current source IS2 of the output voltage adjusting circuit 233 may pull down the voltage levels of the first output voltage VOP and the second output voltage VON based on the feedback voltage VF. In this description, for convenience of explanation, it is assumed that the output voltage adjusting circuit 233 is a pull-up circuit pulling up the voltage levels of the first output voltage VOP and the second output voltage VON.

In some embodiments, the output voltage adjusting circuit 233 may be implemented with various structures. For example, an output voltage adjusting circuit 233 of a common mode feedback circuit 230 may include one current source, and the current source may simultaneously adjust the voltage levels of a first output voltage VOP node and a second output voltage VON node. As another example, the output voltage adjusting circuit 233 may include a current source connected between a power supply voltage VDD line and a first output voltage VOP node and a second output voltage VON node. Alternatively, the output voltage adjusting circuit 233 may include a current source connected between the first output voltage VOP node and the second output voltage VON node and the ground voltage VSS line. The current source in the output voltage adjusting circuit 233 may adjust the voltage levels of the first output voltage VOP and the second output voltage VON based on the feedback voltage VF.

Reference is now made to FIG. 5, which illustrates a circuit diagram of an exemplary amplifying circuit, consistent with some embodiments of the present disclosure. For brevity and convenience of explanation, descriptions identical or similar to FIG. 4 are omitted.

In some embodiments, the amplifying circuit 500 may include a first amplifier 510, a second amplifier 520, and a common mode feedback circuit 530. The first amplifier 510 may include a first transistor AT1, a second transistor AT2, a third transistor AT3, and a fourth transistor AT4, and may include a first current source AS1, a second current source AS2, and a third current source AS3. In some embodiments, the first current source AS1 may be connected between a power voltage VDD line and a first node AN1. Additionally, the first transistor AT1 may be connected between the first node AN1 and the second node AN2. Specifically, the source and drain of the first transistor AT1 may be connected to the first node AN1 and the second node AN2, respectively. The first transistor AT1 may receive the first input voltage VIP1 through a gate. The first transistor AT1 may include a gate receiving the first input voltage VIP1. The second transistor AT2 may be connected between the first node AN1 and the third node AN3. Specifically, the source and drain of the second transistor AT2 may be connected to the first node AN1 and the third node AN3, respectively. The second transistor AT2 may receive the second input voltage VIN1 through a gate. The second transistor AT2 may include a gate receiving the second input voltage VIN1. The third transistor AT3 may be connected between the second node AN2 and the ground voltage VSS line. Specifically, the source and drain of the third transistor AT3 may be connected to the second node AN2 and the ground voltage VSS line, respectively. The fourth transistor AT4 may be connected between the third node AN3 and the ground voltage VSS line. Specifically, the source and drain of the fourth transistor AT4 may be connected to the third node AN3 and the ground voltage VSS line, respectively. The third transistor AT3 and fourth transistor AT4 may receive the bias voltage VB1 through a gate, respectively. The third transistor AT3 and fourth transistor AT4 may respectively include a gate receiving the bias voltage VB1.

In some embodiments, the second current source AS2 may be connected between the first node AN1 and the second node AN2. The second current source AS2 may be coupled in parallel with the first transistor AT1. The third current source AS3 may be connected between the first node AN1 and the third node AN3. The third current source AS3 may be coupled in parallel with the second transistor AT2.

In some embodiments, when the first input voltage VIP1 and the second input voltage VIN1 increase above a predetermined voltage level, the first transistor AT1 and the second transistor AT2 are turned off, and the first current path from the first node AN1 to the second node AN2 through the first transistor AT1 and the second current path from the first node AN1 to the third node AN3 through the second transistor AT2 may be blocked. In such a case, the current supplied from the first current source AS1 may flow to the second node AN2 through the second current source AS2 and to the third node AN3 through the third current source AS3. That is, when the first input voltage VIP1 and the second input voltage VIN1 increase above a predetermined voltage level, the voltage levels of the second node AN2 and the third node AN3 may be increased by the current flowing through the second current source AS2 and the third current source AS3. When the first input voltage VIP1 and the second input voltage VIN1 are below a predetermined voltage level, the first transistor AT1 and the second transistor AT2 are turned on, and the voltage levels of the second node AN2 and the third node AN3 may be increased by the current flowing through the turned-on first transistor AT1 and second transistor AT2. In some embodiments, the current flowing from the first current source AS1 to the second node AN2 and the third node AN3 may flow through different paths (i.e., a path through the first transistor AT1 and the second transistor AT2, or a path through the second current source AS2 and the third current source AS3) based on the voltage levels of the first input voltage VIP1 and the second input voltage VIN1.

The second node AN2 and the third node AN3 may be the output terminals of the first amplifier 510. The voltage of the second node AN2 may be output to the second amplifier 520 as the third input voltage VIN2, and the voltage of the third node AN3 may be output to the second amplifier 520 as the fourth input voltage VIP2.

In some embodiments, the first transistor AT1 and the second transistor AT2 are implemented with P-type transistors, and the third transistor AT3 and the fourth transistor AT4 are implemented with N-type transistors, but are not limited thereto.

In some embodiments, the second amplifier 520 may include a fifth transistor AT5, a sixth transistor AT6, a seventh transistor AT7, and an eighth transistor AT8. The fifth transistor AT5 may be connected between the power voltage VDD line and the fourth node AN4. The source and drain of the fifth transistor AT5 may be connected to the power voltage VDD line and the fourth node AN4, respectively. The sixth transistor AT6 may be connected between the power voltage VDD line and the fifth node AN5. The source and drain of the sixth transistor AT6 may be connected to the power voltage VDD line and the fifth node AN5, respectively. The fifth transistor AT5 and sixth transistor AT6 may receive the bias voltage VB2 through a gate, respectively. The fifth transistor AT5 and sixth transistor AT6 may respectively include a gate receiving the bias voltage VB2. The seventh transistor AT7 may be connected between the fourth node AN4 and the ground voltage VSS line. The source and drain of the seventh transistor AT7 may be connected to the fourth node AN4 and the ground voltage VSS line, respectively. The seventh transistor AT7 may receive the fourth input voltage VIP2 through a gate. The seventh transistor AT7 may include a gate receiving the fourth input voltage VIP2. The eighth transistor may be connected between the fifth node AN5 and the ground voltage VSS line. The source and drain of the eighth transistor AT8 may be connected to the fifth node AN5 and the ground voltage VSS line, respectively. The eighth transistor AT8 may receive the third input voltage VIN2 through a gate. The eighth transistor AT8 may include a gate receiving the third input voltage VIN2.

In some embodiments, when the first input voltage VIP1 and the second input voltage VIN1 increase above a predetermined voltage level, the voltage levels of the second node AN2 and the third node AN3 may be increased by the current flowing through the second current source AS2 and the third current source AS3 in the first amplifier 510. Since the voltage of the second node AN2 corresponds to the third input voltage VIN2, and the voltage of the third node AN3 corresponds to the fourth input voltage VIP2, the voltage levels of the third input voltage VIN2 and the fourth input voltage VIP2 may be increased.

Accordingly, the seventh transistor AT7 and the eighth transistor AT8 may be turned on, and the pull-down current Id may flow through the seventh transistor AT7 and the eighth transistor AT8. Therefore, the voltage levels of the fourth node AN4 and fifth node AN5 may be decreased.

The fourth node AN4 and the fifth node AN5 may be an output terminals of the second amplifier 520. In other words, the voltage level of the fourth node AN4 may be output to the common mode feedback circuit 530 as the second output voltage VON, and the voltage level of the fifth node AN5 may be output to the common mode feedback circuit 530 as the first output voltage VOP.

In some embodiments, the fifth transistor AT5 and the sixth transistor AT6 are implemented with P-type transistors, and the seventh transistor AT7 and the eighth transistor AT8 are implemented with N-type transistors, but are not limited thereto.

In some embodiments, the common mode feedback circuit 530 may generate a common mode output voltage VCMO based on a first output voltage VOP and a second output voltage VON input from the second amplifier 520, and may adjust the voltage levels of the first output voltage VOP and the second output voltage VON based on a comparison result between the common mode output voltage VCMO and a reference voltage VREF so that the common mode output voltage VCMO corresponds to the reference voltage VREF.

FIG. 6 illustrates a circuit diagram of an exemplary amplifying circuit, consistent with some embodiments of the present disclosure.

An amplifying circuit 600 may include a first amplifier 610, a second amplifier 620, and a common mode feedback circuit 630.

In some embodiments, the first amplifier 610 may receive a first input voltage VIP1 and a second input voltage VIN1, and may output a third input voltage VIN2 and a fourth input voltage VIP2. Specifically, when the first input voltage VIP1 and the second input voltage VIN1 are applied to the gate terminals of the first transistor AT1 and the second transistor AT2 of the first amplifier 610, the turn-on degrees of the first transistor AT1 and the second transistor AT2 increase, and the current flowing from the first node AN1 to the second node AN2 through the first transistor AT1 and from the first node AN1 to the third node AN3 through second transistor AT2 increases. Accordingly, the voltage of the second node AN2 and the third node AN3 increases. Since the voltage of the second node AN2 corresponds to the third input voltage VIN2 and the voltage of the third node AN3 corresponds to the fourth input voltage VIP2, the third input voltage VIN2 and the fourth input voltage VIP2, which are the output voltages of the first amplifier 610, increase. Hereinafter, the path of the current flowing to the second node AN2 and the third node AN3 through the first transistor AT1 and the second transistor AT2 may be referred to as a first path.

In some embodiments, the second amplifier 620 may receive a third input voltage VIN2 and a fourth input voltage VIP2, and may output a first output voltage VOP and a second output voltage VON. Specifically, the seventh transistor AT7 and the eighth transistor AT8 of the second amplifier 620 may respectively receive the third input voltage VIN2 and the fourth input voltage VIP2 through a gate, and may control the current flowing to the fourth node AN4 and the fifth node AN5 based on the third input voltage VIN2 and the fourth input voltage VIP2. The fourth node AN4 and the fifth node AN5 may be an output terminals of the second amplifier 620. In other words, the voltage levels of the fourth node AN4 and the fifth node AN5 may be transmitted to the common mode feedback circuit 630 as output voltages (VON, VOP).

In some embodiments, the common mode feedback circuit 630 may receive a first output voltage VOP and a second output voltage VON, and may adjust voltage levels of the first output voltage VOP and the second output voltage VON. The common mode feedback circuit 630 may include a common mode output circuit 631, an output voltage adjusting circuit 633, and an amplifier 635. When the first output voltage VOP and the second output voltage VON decrease due to various causes, the common mode feedback circuit 630 may pull up the voltage levels of the first output voltage VOP and the second output voltage VON. Specifically, as the first output voltage VOP and second output voltage VON decrease, the common mode output voltage VCMO decreases. When the common mode output voltage VCMO becomes lower than the reference voltage VREF, the turn-on degree of the fifth transistor T5 decreases. Therefore, the voltage of node N3 increases. When the voltage of node N3 increases, the turn-on degrees of third transistor T3 and fourth transistor T4 decrease. Specifically, if the voltage of node N3 increases, the gate-source voltages of third transistor T3 and fourth transistor T4 decrease, and, thereby, the current flowing through third transistor T3 and fourth transistor T4 from the power voltage VDD line is decreased. Therefore, the voltage of node N4 decreases. Hereinafter, the voltage of node N4 may be referred to as a first feedback voltage VF1. The first feedback voltage VF1 is transmitted to the first transistor T1 and the second transistor T2. As the first feedback voltage VF1 decreases, the turn-on degrees of the first transistor T1 and second transistor T2 increase. Specifically, when the first feedback voltage VF1 decreases, the gate-source voltages of the first transistor T1 and the second transistor T2 increase, and, thereby, the current I1 flowing from the power supply voltage VDD line to node N1 through the first transistor T1 and the current I2 flowing from the power supply voltage VDD line to node N2 through the second transistor T2 are increased. Therefore, the voltages of the node N1 and the node N2 increase. That is, the voltage levels of the first output voltage VOP and the second output voltage VON increase. Therefore, the common mode output voltage VCMO may be pulled up to the first voltage level (e.g., reference voltage VREF).

The first output voltage VOP and second output voltage VON may be increased when a signal larger than expected is input as the input signal, or a change in the common mode output voltage is caused by noise. As described above with respect to FIG. 2, when the voltage levels of the first output voltage VOP and the second output voltage VON change significantly, the voltage levels of the first input voltage VIP1 and the second input voltage VIN1 may be also changed by the positive feedback loop PFL. As a result, abnormal operations such as amplifier oscillation may be detected.

Referring to FIG. 6, a bias voltage VB0 of a constant level is applied to the gate of the first current source transistor AST1, and current flows from the power supply voltage VDD line to the first node AN1 through the first current source transistor AST1. In some embodiments, if the voltage levels of the first input voltage VIP1 and the second input voltage VIN1 increase, the turn-on degrees of the first transistor AT1 and the second transistor AT2 decrease. That is, the current flows to the first node AN1 through the first current source transistor AST1, but the voltage level of the first node AN1 increases since the first transistor AT1 and the second transistor AT2 are turned off. In some embodiments, the gates of the second current source transistor AST2 and the third current source transistor AST3 are supplied with a bias voltage VB0 substantially the same as the bias voltage VB0 supplied to the gate of the first current source transistor AST1. Since the gate-source voltages of the second current source transistor AST2 and the third current source transistor AST3 increase if the voltage level of the first node AN1 increases, the current I3 flowing through the second current source transistor AST2 and the current I4 flowing through the third current source transistor AST3 increase. In other words, even though the first transistor AT1 and the second transistor AT2 are turned off as the voltage levels of the first input voltage VIP1 and the second input voltage VIN1 increase, the voltage levels of the second node AN2 and the third node AN3 increase since the current flowing through the second current source transistor AST2 connected in parallel with the first transistor AT1 and the third current source transistor AST3 connected in parallel with the second transistor AT2 increases. Hereinafter, the path of the current flowing to the second node AN2 and the third node AN3 through the second current source transistor AST2 and the third current source transistor AST3 may be referred to as a second path.

In some embodiments, the first amplifier 610 may receive input voltages VIP1, and VIN1 of the first level, and may output input voltages VIP2 and VIN2, which are generated based on the current flowing through the first path, to the second amplifier 620. The first amplifier 610 may receive input voltages VIP1 and VIN1 of the second level higher than the first level, and may output input voltages VIP2 and VIN2, which are generated based on the current flowing through the second path, to the second amplifier 620. The current flowing to the second node AN2 and the third node AN3 in the first amplifier 610 may flow through different paths based on the voltage levels of the first input voltage VIP1 and the second input voltage VIN1.

In some embodiments, since the turn-on degrees of the seventh transistor AT7 and the eighth transistor AT8 increase when the voltage levels of the second node AN2 and the third node AN3 increase, the current flowing from the fourth node AN4 to the ground voltage VSS line and the current flowing from the fifth node AN5 to the ground voltage VSS line increase. Accordingly, the voltage levels of the first output voltage VON and the second output voltage VOP decrease. That is, the current flowing through the seventh transistor AT7 and the eighth transistor AT8, as a pull-down current Id, may pull-down the voltage levels of the first output voltage VON and the second output voltage VOP. In this description, the first current source transistor AST1, the second current source transistor AST2, and the third current source transistor AST3 of FIG. 6 are illustrated as implemented with P-type transistors, but not limited thereto.

In some embodiments, by adding a second current source transistor AST2 and a third current source transistor AST3, which are connected in parallel with the first transistor AT1 and the second transistor AT2 and receive a gate voltage substantially the same of the first current source transistor AST1, to the first amplifier 610, the first amplifier 610 may output the input voltage VIP2 and VIN2 to the second amplifier 620 even if it receives high level input voltage VIP1 and VIN1. The second amplifier 620 may receive the input voltages VIP2 and VIN2, and may use the transistors AT7 and AT8 as pull-down paths for the first output voltage VOP and second output voltage VON. Thus, it is advantageous in preventing unnecessary current consumption.

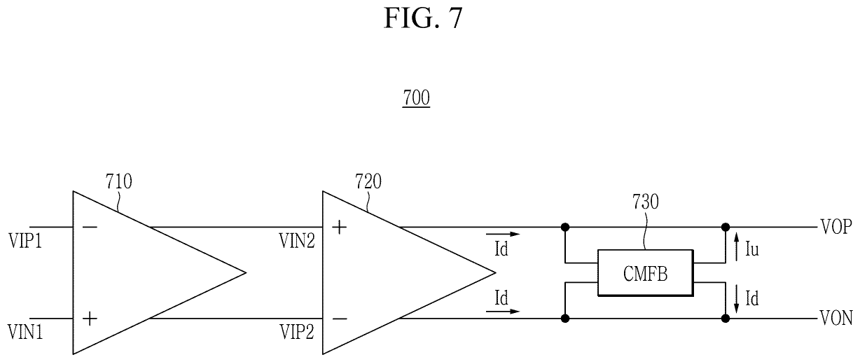

FIG. 7 illustrates a circuit diagram of an exemplary amplifying circuit, consistent with some embodiments of the present disclosure.

In some embodiments, the amplifying circuit 700 may include a first amplifier 710, a second amplifier 720, and a common mode feedback circuit 730. Specifically, the first amplifier 710 may receive a first input voltage VIP1 and a second input voltage VIN1, and may output a third input voltage VIN2 and a fourth input voltage VIP2. The second amplifier 720 may receive the third input voltage VIN2 and the fourth input voltage VIP2, and may output the first output voltage VOP and the second output voltage VON.

In some embodiments, when the voltage levels of the first output voltage VOP and the second output voltage VON change, the common mode feedback circuit 730 may output a pull-up current Iu or a pull-down current Id for controlling the voltage levels of the first output voltage VOP and the second output voltage VON. In some embodiments, the second amplifier 720 may output a pull-down current Id for controlling the voltage levels of the first output voltage VOP and the second output voltage VON.

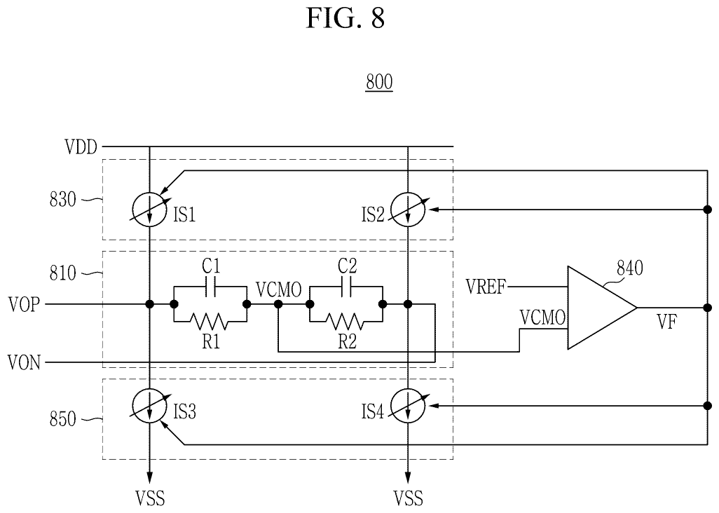

FIG. 8 illustrates a circuit diagram of an exemplary common mode feedback circuit, consistent with some embodiments of the present disclosure. Descriptions identical or similar to those in FIG. 4 are omitted.

In some embodiments, the common mode feedback circuit 800 may include a common mode voltage output circuit 810, a pull-up circuit 830, a pull-down circuit 850, and an amplifier 840. In some embodiments, the common mode voltage output circuit 810 may output a common mode output voltage VCMO based on the first output voltage VOP and the second output voltage VON.

In some embodiments, the amplifier 840 may output a feedback voltage VF based on a comparison result between a common mode output voltage VCMO and a reference voltage VREF.

In some embodiments, the pull-up circuit 830 may include a first variable current source IS1 and a second variable current source IS2, and may pull up voltage levels of the first output voltage VOP and the second output voltage VON based on a feedback voltage VF so that the common mode output voltage VCMO becomes the first voltage level. The first voltage level may be the voltage level of the reference voltage VREF, but is not limited thereto.

In some embodiments, the pull-down circuit 850 may include a third variable current source IS3 and a fourth variable current source IS4. The third variable current source IS3 may be connected between the first output voltage VOP node and the ground voltage VSS line, and the fourth variable current source IS4 may be connected between the second output voltage VON node and the ground voltage VSS line. The pull-down circuit 850 may pull down the first output voltage VOP and the second output voltage VON based on the feedback voltage VF so that the common mode output voltage VCMO becomes the second voltage level. For example, if the voltage level of the common mode output voltage VCMO is higher than the voltage level of the reference voltage VREF, the pull-down currents from the third variable current source IS3 and the fourth variable current source IS4 increases based on the feedback voltage VF received from the amplifier 840, and, thereby, the voltage levels of the first output voltage VOP and the second output voltage VON may pulled down so that the common mode output voltage VCMO becomes the second voltage level. The second voltage level may be the voltage level of the reference voltage VREF, but not limited thereto.

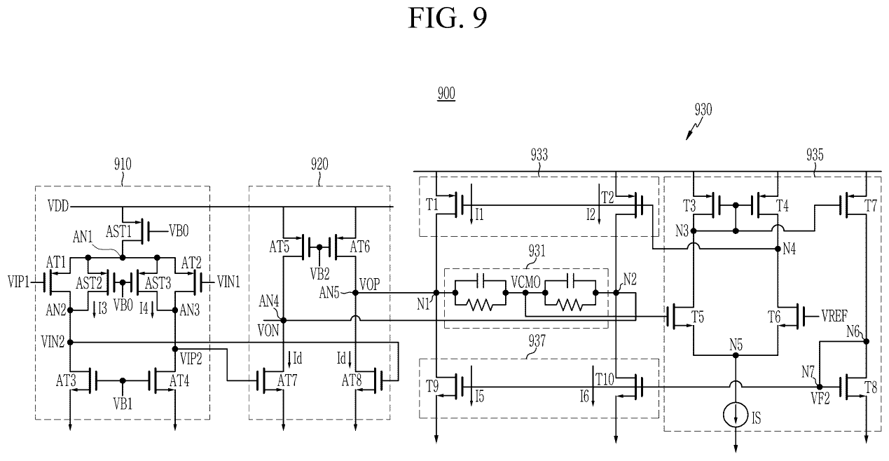

FIG. 9 illustrates a circuit diagram of an exemplary amplifying circuit, consistent with some embodiments of the present disclosure. Since the operations of the first amplifier 910, the second amplifier 920, and the common mode feedback circuit 930 are the same as or similar to the operation method described in FIG. 6, when the first output voltage VOP and the second output voltage VON decrease in the amplifying circuit 900, hereinafter, the operation of the amplifying circuit 900 when the first output voltage VOP and the second output voltage VON in the amplifying circuit 900 increase will be described.

As described in FIG. 6, in some embodiments, if the first output voltage VOP and the second output voltage VON is increased, the first input voltage VIP1 and the second input voltage VIN1 may be increased, and the third input voltage VIN2 and the fourth input voltage VIP2 may be increased by the current flowing through the second current source transistor AST2 and the third current source transistor AST3 of the first amplifier 910. Accordingly, since the turn-on degree of the seventh transistor AT7 and the eighth transistor AT8 increases, a pull-down current Id for lowering the voltage levels of the first output voltage VOP and the second output voltage VON flows through the seventh transistor AT7 and the eighth transistor AT8, and the voltage levels of the first output voltage VOP and the second output voltage VON may be lowered.

In some embodiments, when the first output voltage VOP and the second output voltage VON increase and the common mode output voltage VCMO becomes higher than the reference voltage VREF, the turn-on degree of the fifth transistor T5 of the common mode feedback circuit 930 increases. Thus, the voltage of node N3 decreases since the current flowing through the third transistor T3 flows along node N3 and fifth transistor T5. When the voltage of node N3 decreases, the turn-on degrees of third transistor T3 and fourth transistor T4 increase and the voltage of node N4 increases. As the voltage of node N4 increases, the turn-on degrees of the first transistor T1 and second transistor T2 decrease. Therefore, the amount of current I1 and I2 flowing through the first transistor T1 and second transistor T2 decreases, and the pull-up path pulling up the voltage levels of the first output voltage VOP and the second output voltage VON is blocked. Meanwhile, when the voltage of node N3 decreases, the turn-on degree of seventh transistor T7 increases. Specifically, when the voltage of node N3 decreases, gate-source voltage of the seventh transistor T7 increases, and the current flowing from the power voltage VDD line through the seventh transistor T7 increases. Therefore, the voltage of the node N6 and the node N7 increases. Hereinafter, the voltage of node N7 will be referred to as a second feedback voltage VF2. The voltage of node N7 is transmitted to the ninth transistor T9 and the tenth transistor T10 as the second feedback voltage VF2. As the second feedback voltage VF2 increases, the turn-on degrees of the ninth transistor T9 and the tenth transistor T10 increase. Specifically, since the gate-source voltages of the ninth transistor T9 and the tenth transistor T10 increase when the second feedback voltage VF2 increases, the current I5 flowing from node N1 to the ground voltage VSS line through the ninth transistor T9 and the current I6 flowing from node N2 to the ground voltage VSS line through the tenth transistor T10 increase. Therefore, the voltage of the node N1 and the node N2 decreases. That is, the voltage levels of the first output voltage VOP and the second output voltage VON decrease. Therefore, the common mode output voltage VCMO may be pulled down to a second voltage level (e.g., reference voltage VREF).

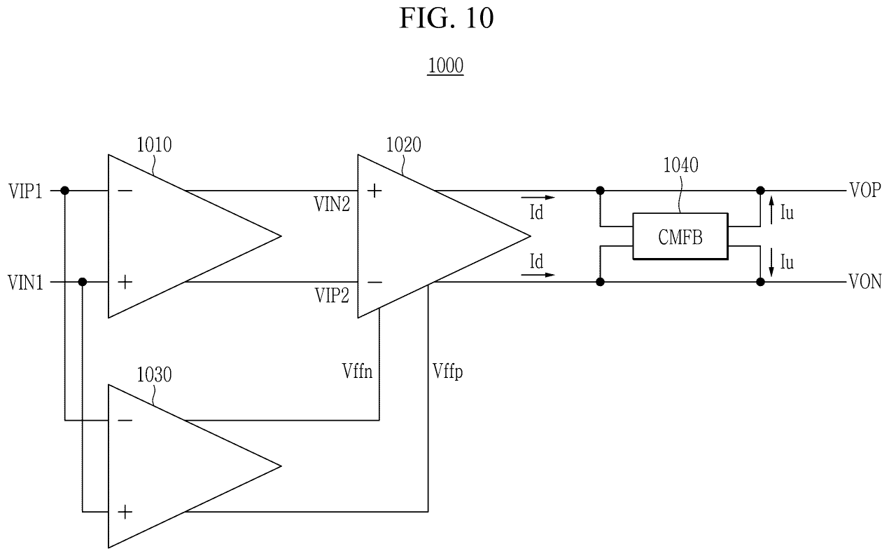

FIG. 10 illustrates a circuit diagram of an exemplary amplifying circuit, consistent with some embodiments of the present disclosure. Amplifying circuit 1000 may include a first amplifier 1010, a second amplifier 1020, a third amplifier 1030, and a common mode feedback circuit 1040. Since the first amplifier 1010, the second amplifier 1020, and the common mode feedback circuit 1040 are substantially identical or similar to the first amplifier 210, the second amplifier 220, and the common mode feedback circuit 230 of FIG. 3, and therefore, descriptions for those are omitted.

In some embodiments, the third amplifier 1030 may receive a first input voltage VIP1 and a second input voltage VIN1, and may output a first feedforward voltage Vffn and a second feedforward voltage Vffp. The third amplifier 1030 may generate the first feedforward voltage Vffn and the second feedforward voltage Vffp based on the first input voltage VIP1 and the second input voltage VIN1 and may output them to the second amplifier 1020. The second amplifier 1020 may generate the first output voltage VOP and the second output voltage VON at a faster speed by amplifying the third input voltage VIN2 and the fourth input voltage VIP2 based on the first feedforward voltage Vffn and the second feedforward voltage Vffp received from the third amplifier 1030. Due to this, the reaction speed of the amplification circuit 1000 can be increased (i.e., the slew rate can be improved).

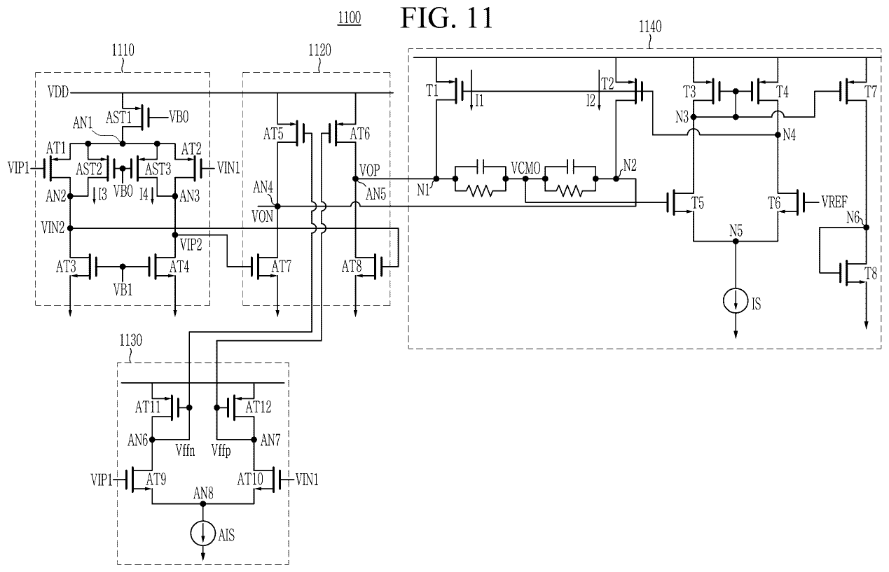

FIG. 11 illustrates a circuit diagram of an exemplary amplifying circuit, consistent with some embodiments of the present disclosure. Descriptions duplicate with those of FIG. 6 are omitted.

Referring to FIG. 11, the third amplifier 1130 in an amplifying circuit 1100 may include an eleventh transistor AT11 connected between a power supply voltage VDD line and a sixth node AN6, a twelfth transistor AT12 connected between the power supply voltage VDD line and the seventh node AN7, a ninth transistor AT9 connected between the sixth node AN6 and the eighth node AN8, a tenth transistor AT10 connected between the seventh node AN7 and the eighth node AN8, and a current source (AIS) connected between the eighth node AN8 and a ground voltage VSS line.

In some embodiments, the gate of the ninth transistor AT9 receive the first input voltage VIP1, and the ninth transistor AT9 may control the current between the sixth node AN6 and the current source (AIS) based on the first input voltage VIP1. The gate of the tenth transistor AT10 receive the second input voltage VIN1, and the tenth transistor AT10 may control the current between the seventh node AN7 and the current source (AIS) based on the second input voltage VIN1.

In some embodiments, the eleventh transistor AT11 may control the current flowing from the power voltage VDD line to the sixth node AN6 based on the voltage level of the sixth node AN6. The twelfth transistor AT12 may control the current flowing from the power voltage VDD line to the seventh node AN7 based on the voltage level of the seventh node AN7. The voltage of the sixth node AN6 may be applied as the first feedforward voltage Vffn to the gate of the fifth transistor AT5 of the second amplifier 1120, and the voltage of the seventh node AN7 may be applied as the second feedforward voltage Vffp to the gate of the sixth transistor AT6 of the second amplifier 1120.

Unlike the case where a bias voltage VB2 of constant level is applied to the gates of the fifth transistor AT5 and the sixth transistor AT6 in the second amplifier 620 in FIG. 6, the first feedforward voltage Vffn and the second feedforward voltage Vffp that vary according to the first input voltage VIP1 and the second input voltage VIN2 are applied to the gates of the fifth transistor AT5 and the sixth transistor AT6, which is advantageous to increase the reaction speed of the second amplifier 620.

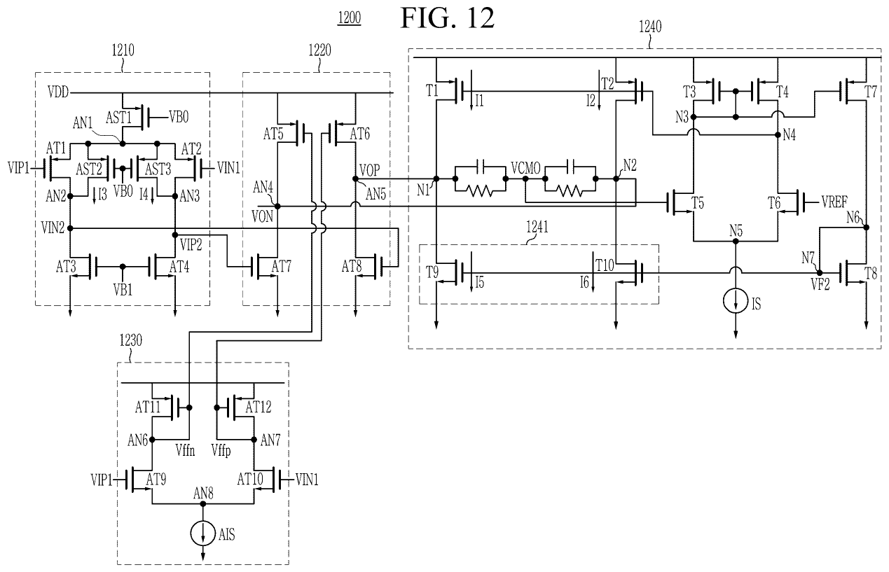

FIG. 12 illustrates a circuit diagram of an exemplary amplifying circuit, consistent with some embodiments of the present disclosure. Specifically, the common mode feedback circuit 1240 of FIG. 12 may include a pull-down circuit 1241.

Because the operations and structures of the first amplifier 1210, the second amplifier 1220, the third amplifier 1230, and the common mode feedback circuit 1240 in FIG. 12 are identical or similar to those in FIG. 9 and FIG. 11, detailed descriptions of the structures and operations of each component are omitted for brevity.

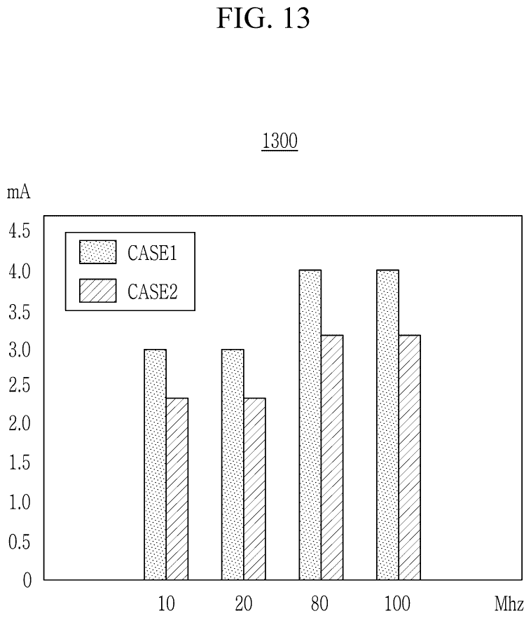

FIG. 13 illustrates a graph comparing the current consumption of an amplifying circuit, consistent with some embodiments of the present disclosure. Specifically, the first case (CASE1) represents the current consumption according to the bandwidth of a conventional amplifying circuit, and the second case (CASE2) represents the current consumption according to the bandwidth of an amplifying circuit.

Referring to FIG. 13, the amplifying circuit may reduce current consumption by approximately 21% at entire bandwidths compared to a conventional amplifying circuit. In some embodiments, by adding a current source that forms a current path as the input voltage of the amplifying circuit increases, some transistors in the amplifying circuit can be utilized as a pull-down path for the output voltage, which is advantageous in reducing the current consumption of the amplifying circuit.

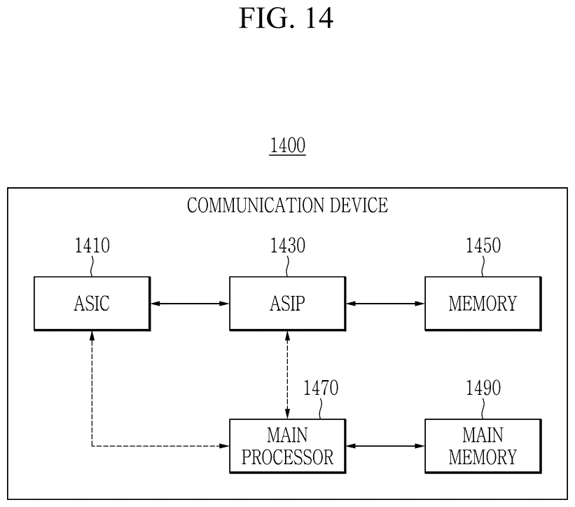

FIG. 14 illustrates a block diagram showing a communication device, consistent with some embodiments of the present disclosure. The communication device 1400 may include an application specific integrated circuit (ASIC) 1410, an application specific instruction set processor (ASIP) 1430, a memory 1450, a main processor 1470, and a main memory 1490. Two or more of ASIC 1410, ASIP 1430, and main processor 1470 may communicate with each other. Also, two or more of ASIC 1410, ASIP 1430, memory 1450, main processor 1470 and main memory 1490 may be embedded in a single chip.

ASIP 1430, which is a customized IC for a specific application, may support a dedicated instruction set for a specific application and execute the instructions included in the instruction set. The memory 1450 may communicate with the ASIP 1430 and, as a non-transitory storage device, may store a plurality of instructions to be executed by the ASIP 1430. For example, memory 1450 may include any type of memory accessible by the ASIP 1430, such as, but not limited to, random access memory (RAM), read only memory (ROM), tape, magnetic disk, optical disk, volatile memory, non-volatile memory, and combinations thereof.

The main processor 1470 may control the communication device 1400 by executing a plurality of instructions. For example, the main processor 1470 may control the ASIC 1410 and ASIP 1430, process data received over a wireless communication network, or process user input to the communication device 1400. The main memory 1490 may communicate with the main processor 1470 and, as a non-transitory storage device, may store a plurality of instructions executed by the main processor 1470. For example, the main memory 1490 may include any type of memory accessible by the main processor 1470, such as, but not limited to, random access memory (RAM), read only memory (ROM), tape, magnetic disk, optical disk, volatile memory, non-volatile memory, and combinations thereof.

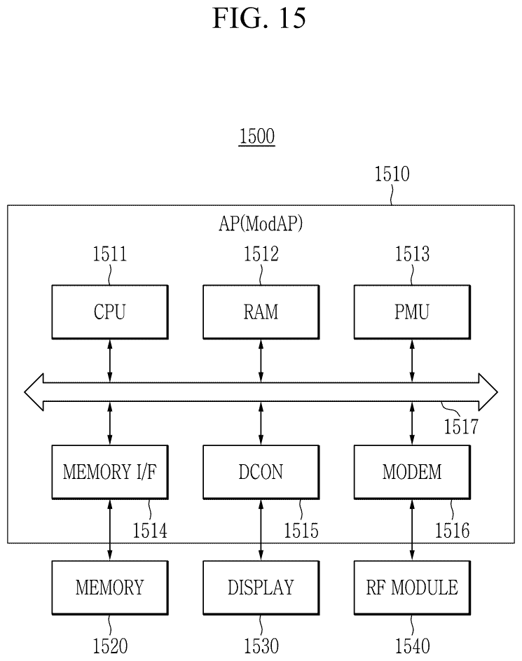

The common mode feedback circuit and the amplifying circuit including the same according to the present disclosure described in FIG. 1 to FIG. 13 may be included in all or part of the communication device 1400 of FIG. 14. FIG. 15 illustrates a block diagram showing a mobile device to which a communication device according to an embodiment is applied.

Referring to FIG. 15, the mobile terminal 1500 may include an application processor (hereinafter referred to as AP) 1510 and memory 1520, a display 1530, and an RF module 1540. In addition, the mobile terminal 1500 may include various components such as a lens, sensor, audio module, etc.

The AP 1510 may be implemented as a system on chip (SoC) and may include a CPU 151, a RAM 1512, a power management unit (PMU) 1513, a memory interface (Memory I/F) 1514, a display controller (DCON) 1515, modem 1516, and a system bus 1517. The AP 1510 may also include various other IPs. The AP 1510 may be referred to as ModAP if the function of a modem chip is integrated inside it.

The CPU 1511 may control the overall operation of AP 1510 and mobile terminal 1500. The CPU 1511 may control the operation of each component of AP 1510. Additionally, the CPU 1511 may be implemented with multi-core. A multi-core is a computing component having two or more independent cores.

The RAM 1512 may temporarily store programs, data, or instructions. For example, programs and/or data stored in memory 1520 may be temporarily stored in RAM 1512 depending on the control of the CPU 1511 or booting code. The RAM 1512 may be implemented with DRAM or SRAM.

The PMU 1513 may manage electric power of each component of AP 1510. The PMU 1513 may also determine the operating status of each component of AP 1510 and control the operation.

The memory interface 1514 may control the overall operation of memory 1520 and control data exchange between each component of AP 1510 and memory 1520. The memory interface 1514 can write data to or read data from the memory 1520 according to the request of CPU 1511.

The display controller 1515 may transmit image data intended to be displayed on the display 1530 to display 1530. The display 1530 may be implemented with a flat panel display (FPD) or a flexible display, such as a liquid crystal display (LCD) or an Organic Light Emitting Diode (OLED).

The modem 1516 may modulate data intended to be transmitted to be appropriate to the wireless environment, and may demodulate received data. The modem 1516 may perform digital communication with RF module 2410.

The RF module 1540 may convert a high frequency signal received through an antenna into a low frequency signal, and may transmit the converted low frequency signal to the modem 1516. Additionally, the RF module 1540 may convert low frequency signals received from the modem 1516 into high frequency signals, and may transmit the converted high frequency signals to the outside of mobile terminal 1500 through an antenna. Additionally, the RF module 1540 may amplify or filter the signal.

The common mode feedback circuits and the amplifying circuits including the same described above with reference to FIG. 1 to FIG. 13 may be implemented in the RF module 1540.

Although the embodiments of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

What is claimed is:

1. An amplifying circuit comprising:
a first amplifier configured to receive first input voltages of a first level, output voltages generated based on a first current flowing through first paths as second input voltages, receive the first input voltages of a second level different from the first level, and output voltages generated based on second current flowing through second paths different from the first paths as the second input voltages;
a second amplifier configured to receive the second input voltages and adjust voltage levels of output voltages generated by amplifying the second input voltages; and
a common mode feedback circuit configured to receive a first output voltage among the output voltages through a first output node, receive a second output voltage among the output voltages through a second output node, and adjust voltage levels of the first output voltage and the second output voltage according to the strength of a feedback voltage based on the first output voltage, the second output voltage, and a reference voltage.

2. The amplifying circuit of claim 1, wherein:
the first paths comprise:
a first transistor connected between a first node and a second node and comprising a gate receiving one of the first input voltages; and
a second transistor connected between the first node and a third node and comprising a gate receiving remainder of the first input voltages;
the second paths comprise:
a third transistor connected between the first node and the second node and comprising a gate receiving a bias voltage; and
a fourth transistor connected between the first node and the third node and comprising a gate receiving the bias voltage;
and
the second amplifier configured to receive one of the second input voltages through the second node and receive remainder of the second input voltages through the third node.

3. The amplifying circuit of claim 2, further comprising a fifth transistor connected between a power voltage line and the first node and comprising a gate receiving the bias voltage.

4. The amplifying circuit of claim 1, wherein the second amplifier comprises:
a sixth transistor connected between the first output node and a ground voltage line and comprising a gate receiving one of the second input voltages; and
a seventh transistor connected between the second output node and the ground voltage line and comprising a gate receiving remainder of the second input voltages.

5. The amplifying circuit of claim 4, wherein:
the sixth transistor configured to pull down a voltage level of the first output node according to the one of the second input voltages generated based on the second current; and
the seventh transistor configured to pull down a voltage level of the second output node according to the remainder of the second input voltages generated based on the second current.

6. The amplifying circuit of claim 1, wherein the second level is higher than the first level.

7. The amplifying circuit of claim 1, wherein
the common mode feedback circuit comprises:
a first circuit configured to generate a common mode voltage determined based on the first output voltage and the second output voltage;
a second circuit configured to generate the feedback voltage based on difference between the common mode voltage and the reference voltage; and
a third circuit configured to pull up a voltage level of the first output node and a voltage level of the second output node based on the feedback voltage so that the common mode voltage becomes the first voltage level.

8. The amplifying circuit of claim 7, wherein
the third circuit comprises:
a first variable current source connected to a power voltage line and the first output node and pulling up a voltage level of the first node based on the feedback voltage so that the common mode voltage becomes the first voltage level; and
a second variable current source connected to the power voltage line and the second output node and pulling up a voltage level of the second node based on the feedback voltage so that the common mode voltage becomes the first voltage level.

9. The amplifying circuit of claim 7, wherein the first voltage level is a voltage level of the reference voltage.

10. The amplifying circuit of claim 1, wherein
the common mode feedback circuit comprises:
a fourth circuit configured to generate a common mode voltage determined based on the first output voltage and the second output voltage;
a fifth circuit configured to generate the feedback voltage based on difference between the common mode voltage and the reference voltage, and
a sixth circuit configured to pull down a voltage level of the first output node and the voltage level of the second output node based on the feedback voltage so that the common mode voltage becomes the second voltage level.

11. The amplifying circuit of claim 10, wherein
the sixth circuit comprises:
a third variable current source connected to the first output node and a ground voltage line and configured to pull down the voltage level of the first output node based on the feedback voltage so that the common mode voltage becomes the second voltage level; and
a fourth variable current source connected to the second output node and the ground voltage line and configured to pull down the voltage level of the second output node based on the feedback voltage so that the common mode voltage becomes the second voltage level.

12. An amplifying circuit comprising:
a first amplifier circuit comprising:
a first transistor configured to receive a first input voltage signal, the first transistor being connected to a first node and a second node;
a first current source located between a power voltage line and the first node and configured to supply a first current to the first transistor; and
a second current source located between the first node and the second node and connected in parallel with the first transistor, wherein
when a first voltage level of the first input voltage signal is lower than a first predetermined voltage level, the first current is configured to flow in a first path from the first node to the second node through the first transistor, the first transistor configured to output a third input voltage to the second node based on the first current flowing through the first transistor, and
when the first voltage level of the first input voltage signal is higher than the first predetermined voltage level, the first current is configured to flow in a second path from the first node to the second node through the second current source.

13. The amplifying circuit of claim 12, wherein the first amplifier circuit further comprises:
a second transistor configured to receive a second input voltage signal, the second transistor being connected to the first node and a third node; and
a third current source located between the first node and the third node and connected in parallel with the second transistor, wherein
when a second voltage level of the second input voltage signal is lower than a second predetermined voltage level, a second current supplied by the first current source is configured to flow in the first path from the first node to the third node through the second transistor, the second transistor configured to output a fourth input voltage to the third node based on the second current flowing through the second transistor, and
when the second voltage level of the second input voltage signal is higher than the second predetermined voltage level, the second current is configured to flow in the second path from the first node to the third node through the third current source.

14. The amplifying circuit of claim 13, wherein the first amplifier circuit further comprising:
a third transistor connected to the second node and a ground voltage line, the third transistor configured to receive the third input voltage, and wherein the second node is configured to be a first output node of the first amplifier circuit, and
a fourth transistor connected to the third node and the ground voltage line, the fourth transistor configured to receive the fourth input voltage, and wherein the third node is configured to be a second output node of the first amplifier circuit.

15. The amplifying circuit of claim 14, further comprising a second amplifier circuit, the second amplifier circuit comprising:
a fifth transistor connected between the power voltage line and a fourth node, the fourth node configured to be a third output node of the second amplifier circuit;
a sixth transistor connected between the power voltage line and a fifth node, the fifth node configured to be a fourth output node of the second amplifier circuit;
a seventh transistor connected between the fourth node and the ground voltage line, the seventh transistor comprising a first gate terminal configured to receive the fourth input voltage; and
an eighth transistor connected between the fifth node and the ground voltage line, the eighth transistor comprising a second gate terminal configured to receive the third input voltage.

16. The amplifying circuit of claim 15, further comprising a common mode feedback circuit configured to:
receive a voltage of the third output node and a voltage of the fourth output node associated with the second amplifier circuit; and
generate a common mode output voltage based on the voltage of third output node and the voltage of fourth output node received from the second amplifier circuit.

17. The amplifying circuit of claim 16, wherein the common mode feedback circuit comprises:
a first circuit configured to generate the common mode output voltage based on the voltage of third output node and the voltage of fourth output node ;
a second circuit configured to generate a feedback voltage based on the comparison between the common mode output voltage and the reference voltage; and
a third circuit configured to pull up the voltage of third output node and the voltage of fourth output node based on the feedback voltage so that the common mode output voltage corresponds to the reference voltage.

18. The amplifying circuit of claim 17, wherein the third circuit comprises:
a first variable current source connected to the power voltage line and the third output node and configured to pull up the voltage of third output node based on the feedback voltage; and
a second variable current source connected to the power voltage line and the fourth output node and configured to pull up the voltage of fourth output node based on the feedback voltage.

19. A radio-frequency (RF) circuit comprising:
a transmission signal (TX) filter configured to filter a first transmission signal input from an external device and form a filtered first transmission signal;
a transmission signal (TX) mixer configured to receive the filtered first transmission signal and up-convert a frequency of the filtered first transmission signal to generate a second transmission signal; and
a power amplifier configured to receive the second transmission signal and amplify the second transmission signal,
wherein the TX filter comprises:
a first amplifier configured to:
receive the first transmission signal and an inverted signal of the first transmission signal as a first input signal and a second input signal, respectively,
amplify each of the first input signal and the second input signal, and
output a third input signal and a fourth input signal corresponding to an amplified first input signal and an amplified second input signal, respectively;
a second amplifier configured to:
receive the third input signal and the fourth input signal, amplify the third input signal and the fourth input signal, output a first output signal and a second output signal, and
adjust a voltage level of the first and the second output signal based on a voltage level of the third and the fourth input signal; and
a common mode feedback circuit configured to:
receive the first output signal through a first output node,
receive the second output signal through a second output node,
generate a feedback current based on a reference voltage and a common mode output voltage determined based on the first output signal and the second output signal, and
adjust a voltage level of the first output node and a voltage level of the second output node based on the feedback current.

20. The RF circuit of claim 19, wherein the common mode feedback circuit comprises at least one of:
a first circuit configured to increase the voltage level of the first output signal and the second output signal by increasing the feedback current that pulls up the voltage level of the first output node and the voltage level of the second output node when the common mode output voltage is lower than the reference voltage; and
a second circuit configured to decrease the voltage level of the first output signal and the second output signal by increasing the feedback current that pulls down the voltage level of the first output node and the voltage of the second output node when the common mode output voltage is higher than the reference voltage.
